(19) United States
(12) Patent Application Publication
(10) Pub. No.: US 2019/0250470 A1
(43) Pub. Date: Aug. 15, 2019

(54) DISPLAY DEVICE

(71) Applicant: Au Optronics Corporation, Hsinchu (TW)

(72) Inventors: Sheng-Miao Huang, Taoyuan City (TW); Yu-Sheng Huang, Kaohsiung City (TW)

(73) Assignee: Au Optronics Corporation, Hsinchu (TW)

(21) Appl. No.: 15/974,716

(22) Filed: May 9, 2018

(30) Foreign Application Priority Data
Feb. 13, 2018 (TW) 107105105

(51) Int. Cl. G02F 1/1343; G02F 1/1335; G02F 1/1368; G02F 1/1333; G02F 1/1362; G02F 1/1339; H01L 27/12; H01Q 1/22

(52) U.S. Cl. CPC G02F 1/134309; G02F 1/133512; G02F 1/133514; G02F 1/1368; G02F 1/133345; G02F 1/136286; G02F 2001/13685; H01L 27/124; G02F 1/133602; H01Q 1/22; G02F 2001/133357; G02F 2201/121; G02F 2201/123; G02F 1/1339

(57) ABSTRACT

A display device including a display panel and a circuit board is provided. The display panel has a plurality of sensing units. Each sensing unit includes a pixel array layer, a first antenna, a planarization layer, a spacer and a display medium layer. The pixel array layer is disposed on a first substrate, and includes a plurality of scan lines, a plurality of data lines and a plurality of pixel structures. The first antenna is disposed on the first substrate, and corresponding to the scan lines and the data lines. The first antenna is electrically connected to one of the data lines. The planarization layer is disposed on a second substrate opposite to the first substrate, and has a recess pattern which at least partially overlaps with the first antenna in the normal direction of the first substrate. The spacer is disposed on the planarization layer and extends to the pixel array layer. The display medium layer is disposed between the first substrate and the second substrate. The circuit board is located under the display panel, and has a plurality of second antennas corresponding to the first antennas.

### CROSS-REFERENCE TO RELATED APPLICATION

This application claims the priority benefit of Taiwan application serial no. 107105105, filed on Feb. 13, 2018. The entirety of the above-mentioned patent application is hereby incorporated by reference herein and made a part of this specification.

### BACKGROUND

### Technical Field

The disclosure relates to a display device, and more particularly, relates to a display device that transmits signals through wireless transmission.

### Related Art

In recent years, with the continuous improvement of display technology, display devices with narrow frames have gradually attracted the attention of the market. Many manufacturers are devoted to research and development for relevant technologies related to narrow frames. At present, although an increasing demand for high resolution can be satisfied by increasing the numbers of gate drivers and source drivers used in the display device, an area of a non-display region (or also known as a frame) may become larger by doing so. Thus, finding a way to save the number of the gate drivers or the source drivers used in order to reduce the space used is truly one of the goals developers wish to achieve.

### SUMMARY

The disclosure is directed to a display device, which is capable of transmitting a pixel signal through wireless transmission and preventing a gap between two substrates from being affected, so as to provide favorable display quality.

The display device of the disclosure includes a display panel and a circuit board. The display panel has a plurality of sensing units, and each of the sensing units includes a pixel array layer, a first antenna, a planarization layer, at least one spacer and a display medium layer. The pixel array layer is disposed on a first substrate, and includes a plurality of scan lines, a plurality of data lines and a plurality of pixel structures, wherein each of the pixel structures is electrically connected to one of the scan lines and one of the data lines. The first antenna is disposed on the first substrate, and disposed corresponding to the scan lines and the data lines, wherein the first antenna is electrically connected to one of the data lines. The planarization layer is disposed on a second substrate, wherein the second substrate is disposed opposite to the first substrate. The planarization layer has a recess pattern, wherein the recess pattern at least partially overlaps with the first antenna in a normal direction of the first substrate. The at least one spacer is disposed on the planarization layer, wherein the at least one spacer extends to the pixel array layer. The display medium layer is disposed between the first substrate and the second substrate. The circuit board is disposed under the display panel, wherein the circuit board has a plurality of second antennas disposed corresponding to the first antennas.

Based on the above, in the display device of the disclosure, with the sensing unit in the display panel including the first antenna electrically connected to the data line, the planarization layer having the recess pattern that at least partially overlaps with the first antenna in the normal direction of the first substrate and the circuit board including the second antennas disposed corresponding to the first antennas, the display device can transmit the pixel signal through wireless transmission and prevent the gap between the first substrate and the second substrate from being affected, so as to provide favorable display quality.

To make the above features and advantages of the disclosure more comprehensible, several embodiments accompanied with drawings are described in detail as follows.

### BRIEF DESCRIPTION OF THE DRAWINGS

FIG. 1 is a schematic partial three-dimensional view of a display device according to an embodiment of the disclosure.

FIG. 2 is a schematic partial top view of the display panel in FIG. 1.

FIG. 3 is a schematic cross-sectional view of FIG. 2 taken along a section line I-I′.

FIG. 4 is a schematic three-dimensional view of a disposition relationship between a recess pattern C1 and a first antenna A1 in FIG. 3.

FIG. 5 is a schematic cross-sectional view of FIG. 2 taken along a section line II-II′.

FIG. 6 is a schematic partial cross-sectional view of a display panel according to another embodiment of the disclosure.

FIG. 7 is a schematic partial cross-sectional view of a display panel according to another embodiment of the disclosure.

FIG. 8 is a schematic partial cross-sectional view of a display panel according to another embodiment of the disclosure.

FIG. 9 is a schematic partial cross-sectional view of a display panel according to another embodiment of the disclosure.

### DESCRIPTION OF THE EMBODIMENTS

Reference will now be made in detail to the present preferred embodiments of the disclosure, examples of which are illustrated in the accompanying drawings. Wherever possible, the same reference numbers are used in the drawings and the description to refer to the same or like parts.

In the accompanying drawings, thicknesses of layers, films, panels, regions and so on are exaggerated for clarity. Throughout the specification, the same reference numerals in the accompanying drawings denote the same elements. It should be understood that when an element such as a layer, film, region or substrate is referred to as being “on” or “connected to” another element, it can be directly on or connected to the other element, or intervening elements may also be present. In contrast, when an element is referred to as being “directly on” or “directly connected to” another element, there are no intervening elements present. As used herein, the term “connected” may refer to physically connected and/or electrically connected (coupled). Therefore, intervening elements may be present in an electrical connection (coupling) between two elements.

The term “about,” “approximately,” or “substantially” as used herein is inclusive of the stated value and means within an acceptable range of deviation for the particular value as determined by persons of ordinary skill in the art, considering the measurement in question and the error associated with measurement of the particular quantity (i.e., the limitations of the measurement system). For example, “about” may mean within one or more standard deviations, or within, for example, ±30%, ±20%, ±15%, ±10%, ±5% of the stated value. Moreover, a relatively acceptable range of deviation or standard deviation may be chosen for the term “about,” “approximately,” or “substantially” as used herein based on optical properties, etching properties or other properties, instead of applying one standard deviation across all the properties.

Unless otherwise defined, all terms (including technical and scientific terms) used herein have the same meaning as commonly understood by persons of ordinary skill in the art. It will be further understood that terms, such as those defined in commonly used dictionaries, should be interpreted as having a meaning that is consistent with their meaning in the context of the relevant art and the disclosure and will not be interpreted in an idealized or overly formal sense unless expressly so defined herein.

Exemplary embodiments are described herein with reference to schematic cross-sectional views illustrating idealized embodiments. Hence, variations of shapes resulting from manufacturing technologies and/or tolerances, for instance, are to be expected. The embodiments described herein should not be construed as being limited to the particular shapes of regions as illustrated herein but are to include deviations in shapes that result, for example, from manufacturing. For instance, regions shown or described as being flat may typically have rough and/or non-linear features. Besides, the acute angle as shown may be round. That is, the regions shown in the drawings are schematic in nature, and their shapes are not intended to show the exact shape of the regions, and are not intended to limit the scope of the claims.

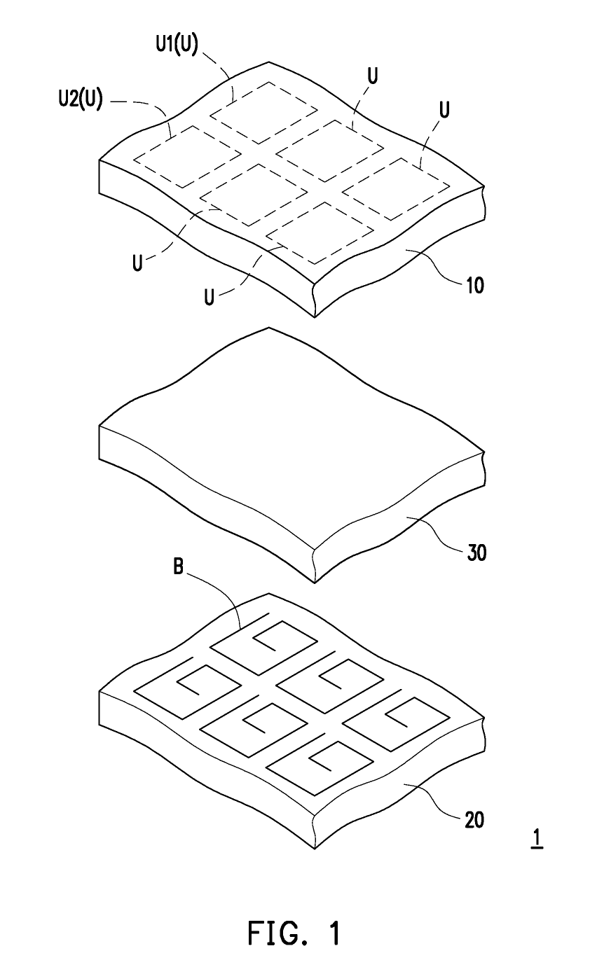

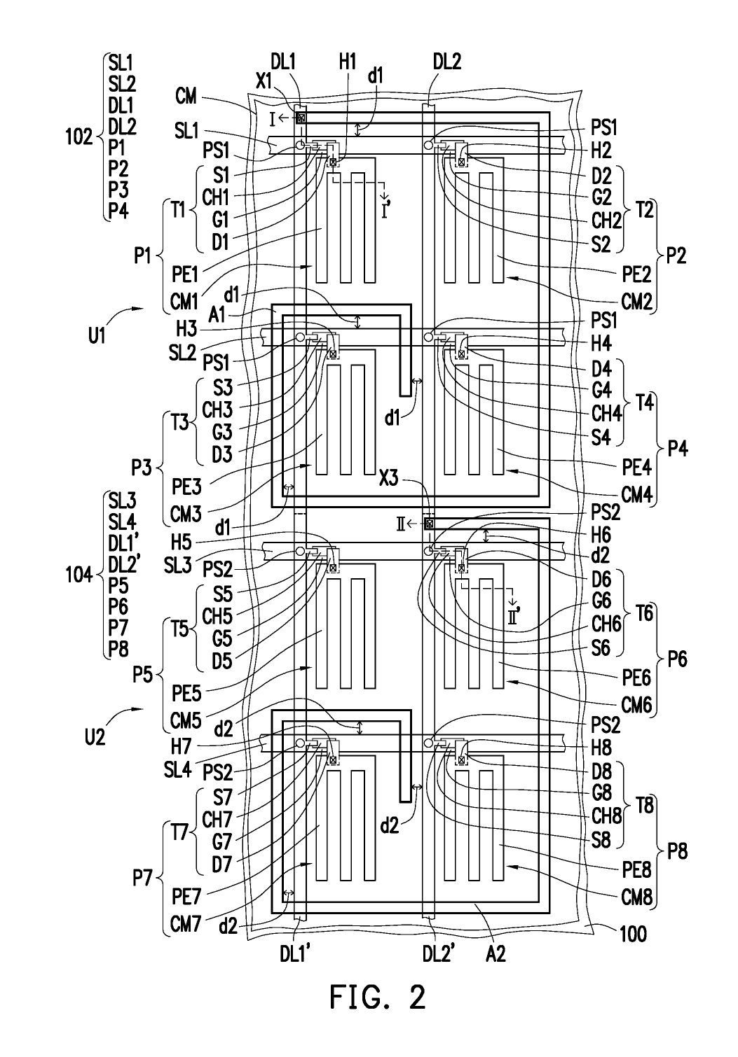

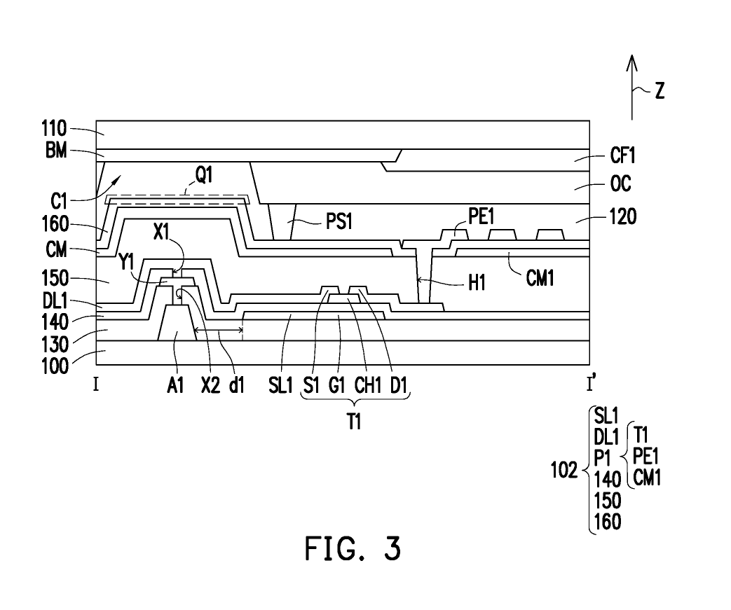

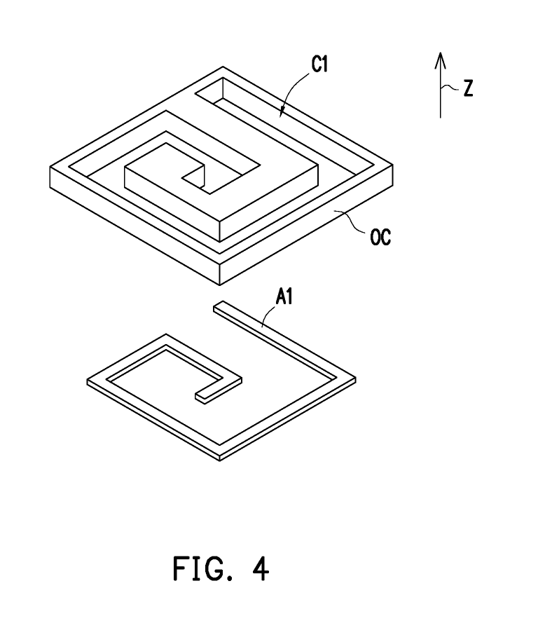

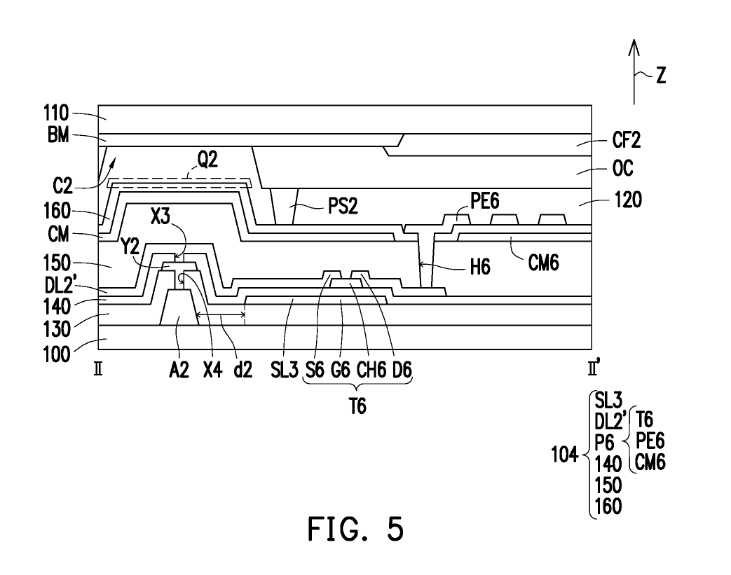

FIG. 1 is a schematic partial three-dimensional view of a display device according to an embodiment of the disclosure. FIG. 2 is a schematic partial top view of the display panel in FIG. 1. FIG. 3 is a schematic cross-sectional view of FIG. 2 taken along a section line I-I′. FIG. 4 is a schematic three-dimensional view of a disposition relationship between a recess pattern C1 and a first antenna A1 in FIG. 3. FIG. 5 is a schematic cross-sectional view of FIG. 2 taken along a section line II-II′.

With reference to FIG. 1, a display device 1 includes a display panel 10 and a circuit board 20. In addition, the display device 1 may optionally further include a backlight module 30. The display device 1 will be described in detail below with reference to FIG. 2 to FIG. 5.

Referring to FIG. 1 to FIG. 4 together, the display panel 10 includes a first substrate 100, a second substrate 110 and a plurality of sensing units U. In this embodiment, the sensing units U are arranged in an array between the first substrate 100 and the second substrate 110. In this embodiment, the sensing units U include a sensing unit U1 and a sensing unit U2. It is worth noting that, for clarity, only two sensing units U (i.e., the sensing unit U1 and the sensing unit U2) are used as an example in the description. Nonetheless, according to the following description regarding the sensing unit U1 and the sensing unit U2, persons of ordinary skill in the art should be able to understand the overall structure or layout of the display panel 10

The first substrate 100 may be made of, for example, glass, quartz, or organic polymer. The second substrate 110 is located opposite to the first substrate 100. The second substrate 110 may be made of, for example, glass, quartz, or organic polymer.

Referring back to FIG. 2 to FIG. 4, the sensing unit U1 includes a pixel array layer 102, a first antenna A1, a planarization layer OC, a plurality of spacers PS1 and a display medium layer 120. In addition, the sensing unit U1 may further include a light shielding pattern layer BM, a plurality of color filter patterns CF1, an insulation layer 130, an insulation layer 140, a protection layer 150 and an intermediate insulation layer 160. For illustrative purposes, components including the insulation layer 130, the insulation layer 140, the protection layer 150, the intermediate insulation layer 160, the display medium layer 120, the planarization layer OC, the color filter patterns CF1 and the light shielding pattern layer BM are omitted in FIG. 2.

The pixel array layer 102 is disposed on the first substrate 100. In this embodiment, the pixel array layer 102 includes a scan line SL1, a scan line SL2, a data line DL1, a data line DL2 and a plurality of pixel structures P1 to P4. An extending direction of the scan lines SL1 and SL2 is different from an extending direction of the data lines DL1 and DL2. Preferably, the extending direction of the scan lines SL1 and SL2 is perpendicular to the extending direction of the data lines DL1 and DL2, but is not limited thereto. Further, in this embodiment, the scan lines SL1 and SL2 and the data lines DL1 and DL2 may be located in different layers, and the insulation layer 140 (described in detail later) may be interposed between the scan lines SL1 and SL2 and the data lines DL1 and DL2. The scan lines SL1 and SL2 and the data lines DL1 and DL2 are generally made of a metal material considering conductivity. However, the disclosure is not limited to the above. According to other embodiments, the scan lines SL1 and SL2 and the data lines DL1 and DL2 may also be made of, for example, other conductive materials such as an alloy, a nitride of said metal material, an oxide of said metal material, an oxynitride of said metal material, or a stacked layer of said metal material and said other conductive materials.

In this embodiment, the pixel structure P1 includes an active element T1, a first electrode PE1 and a second electrode CM1; the pixel structure P2 includes an active element T2, a first electrode PE2 and a second electrode CM2; the pixel structure P3 includes an active element T3, a first electrode PE3 and a second electrode CM3; and the pixel structure P4 includes an active element T4, a first electrode PE4 and a second electrode CM4.

In this embodiment, the active element T1 is electrically connected to the scan line SL1 and the data line DL1; the active element T2 is electrically connected to the scan line SL1 and the data line DL2; the active element T3 is electrically connected to the scan line SL2 and the data line DL1; and the active element T4 is electrically connected to the scan line SL2 and the data line DL2. From another perspective, in this embodiment, the pixel structure P1 is electrically connected to the scan line SL1 and the data line DL1; the pixel structure P2 is electrically connected to the scan line SL1 and the data line DL2; the pixel structure P3 is electrically connected to the scan line SL2 and the data line DL1; and the pixel structure P4 is electrically connected to the scan line SL2 and the data line DL2. Therefore, it can be known that the active element (e.g., the active element T1) of the pixel structure (e.g., the pixel structure P1) is electrically connected to the corresponding scan line (e.g., the scan line SL1) and the corresponding data line (e.g., the data line DL1).

For instance, in this embodiment, the active element T1 includes a gate G1, a channel layer CH1 disposed corresponding to the gate G1, and a drain D1 and a source S1 electrically connected to the channel layer CH1; the active element T2 includes a gate G2, a channel layer CH2 disposed corresponding to the gate G2, and a drain D2 and a source S2 electrically connected to the channel layer CH2; the active element T3 includes a gate G3, a channel layer CH3 disposed corresponding to the gate G3, and a drain D3 and a source S3 electrically connected to the channel layer CH3; and the active element T4 includes a gate G4, a channel layer CH4 disposed corresponding to the gate G4, and a drain D4 and a source S4 electrically connected to the channel layer CH4.

In this embodiment, a partial region of the scan line SL1 is used as the gate G1 and the gate G2, and a partial region of the scan line SL2 is used as the gate G3 and the gate G4. In other words, the gate G1, the gate G2 and the scan line SL1 are electrically connected to each other, and the gate G3, the gate G4 and the scan line SL2 are electrically connected to each other. From another perspective, the partial region of the scan line used as the gates includes a part extended from the scan line used as the gates or a part of the scan line itself used as the gates. In addition, in this embodiment, the source S1, the source S3 and the data line DL1 are a continuous conductive pattern, and the source S2, the source S4 and the data line DL2 are a continuous conductive pattern. In other words, the source S1, the source S3 and the data line DL1 are electrically connected to each other, and the source S2, the source S4 and the data line DL2 are electrically connected to each other. From another perspective, in this embodiment, when a control signal is input to the scan line SL1, the scan line SL1, the gate G1 and the gate G2 are electrically connected to each other; when the control signal is input to the scan line SL2, the scan line SL2, the gate G3 and the gate G4 are electrically connected to each other; when a pixel signal is input to the data line DL1, the data line DL1, the source S1 and the source S3 are electrically connected to each other; and when the pixel signal is input to the data line DL2, the data line DL2, the source S2 and the source S4 are electrically connected to each other.

The channel layer CH1 is located above the gate G1; the channel layer CH2 is located above the gate G2; the channel layer CH3 is located above the gate G3; and the channel layer CH4 is located above the gate G4. The source S1 and the drain D1 are located above the channel layer CH1; the source S2 and the drain D2 are located above the channel layer CH2; the source S3 and the drain D3 are located above the channel layer CH3; and the source S4 and the drain D4 are located above the channel layer CH4. For instance, in this embodiment, at least one of the active element T1, the active element T2, the active element T3 and the active element T4 is referred to as a bottom-gate thin film transistor, but the disclosure is not limited thereto. In other embodiments, at least one of the active element T1, the active element T2, the active element T3 and the active element T4 may also be a top-gate thin film transistor, a three-dimensional thin film transistor or other suitable thin film transistors.

In this embodiment, the insulation layer 140 covers the gate G1 of the active element T1, the gate G2 of the active element T2, the gate G3 of the active element T3, and the gate G4 of the active element T4. In addition, the protection layer 150 may cover the active element T1, the active element T2, the active element T3 and the active element T4. The insulation layer 140 and the protection layer 150 may be made of an inorganic material, an organic material or a combination thereof. The inorganic material is, for example, silicon oxide, silicon nitride, silicon oxynitride or a stacked layer of at least two of the above materials. The organic material is, for example, a polymeric material, such as a polyimide-based resin, an epoxy-based resin, an acrylic-based resin.

In this embodiment, the first electrode PE1 is electrically connected to the drain D1 of the active element T1 via a contact window H1; the first electrode PE2 is electrically connected to the drain D2 of the active element T2 via a contact window H2; the first electrode PE3 is electrically connected to the drain D3 of the active element T3 via a contact window H3; and the first electrode PE4 is electrically connected to the drain D4 of the active element T4 via a contact window H4. From another perspective, in this embodiment, the first electrode PE1, the first electrode PE2, the first electrode PE3 and the first electrode PE4 may be used as pixel electrodes of the pixel structure P1, the pixel structure P2, the pixel structure P3 and the pixel structure P4 respectively.

In this embodiment, materials of the first electrode PE1, the first electrode PE2, the first electrode PE3 and the first electrode PE4 may include a metal oxide conductive material, such as indium tin oxide, indium zinc oxide, aluminum tin oxide, aluminum zinc oxide, indium gallium zinc oxide, other suitable oxides, or a stacked layer of at least two of the above. In addition, in this embodiment, the first electrode PE1, the first electrode PE2, the first electrode PE3 and the first electrode PE4 respectively include a plurality of stripe electrode patterns.

In this embodiment, the second electrode CM1 is disposed corresponding to the first electrode PE1; the second electrode CM2 is disposed corresponding to the first electrode PE2; the second electrode CM3 is disposed corresponding to the first electrode PE3; and the second electrode CM4 is disposed corresponding to the first electrode PE4. For instance, in this embodiment, the second electrode CM1, the second electrode CM2, the second electrode CM3 and the second electrode CM4 are connected to each other to form a part of a common electrode layer CM. In this embodiment, a part of the common electrode layer CM corresponding to the first electrode PE1 is used as the second electrode CM1 of the pixel structure P1; a part of the common electrode layer CM corresponding to the first electrode PE2 is used as the second electrode CM2 of the pixel structure P2; a part of the common electrode layer CM corresponding to the first electrode PE3 is used as the second electrode CM3 of the pixel structure P3; and a part of the common electrode layer CM corresponding to the first electrode PE4 is used as the second electrode CM4 of the pixel structure P4. From another perspective, in this embodiment, the second electrode CM1, the second electrode CM2, the second electrode CM3 and the second electrode CM4 are used as common electrodes of the pixel structure P1, the pixel structure P2, the pixel structure P3 and the pixel structure P4 respectively. In other embodiments, the second electrode CM1, the second electrode CM2, the second electrode CM3 and the second electrode CM4 are used as the pixel electrodes of the pixel structure P1, the pixel structure P2, the pixel structure P3 and the pixel structure P4 respectively, spaced apart from each other, and electrically connected to the corresponding active element; and the first electrode PE1, the first electrode PE2, the first electrode PE3 and the first electrode PE4 are used as the common electrodes of the pixel structure P1, the pixel structure P2, the pixel structure P3 and the pixel structure P4 respectively.

In this embodiment, the intermediate insulation layer 160 is further disposed between the common electrode layer CM and the first electrode PE1, the first electrode PE2, the first electrode PE3, the first electrode PE4, such that the common electrode layer CM and the first electrode PE1, the first electrode PE2, the first electrode PE3, the first electrode PE4 are structurally separated from each other. In addition, with reference to FIG. 2 and FIG. 3, the first electrode PE1, the first electrode PE2, the first electrode PE3 and the first electrode PE4 are disposed above the intermediate insulation layer 160, and the common electrode layer CM is disposed under the intermediate insulation layer 160. From another perspective, in this embodiment, the second electrode CM1, the second electrode CM2, the second electrode CM3 and the second electrode CM4 are correspondingly disposed under the first electrode PE1, the first electrode PE2, the first electrode PE3 and the first electrode PE4 respectively. In other embodiments, the second electrode CM1, the second electrode CM2, the second electrode CM3, and the second electrode CM4 are correspondingly disposed above the first electrode PE1, the first electrode PE2, the first electrode PE3 and the first electrode PE4 respectively, wherein the second electrode CM1, the second electrode CM2, the second electrode CM3 and the second electrode CM4 are used as the pixel electrodes of the pixel structure P1, the pixel structure P2, the pixel structure P3 and the pixel structure P4 respectively, spaced apart from each other, and electrically connected to the corresponding active element; and the first electrode PE1, the first electrode PE2, the first electrode PE3 and the first electrode PE4 are used as the common electrodes of the pixel structure P1, the pixel structure P2, the pixel structure P3 and the pixel structure P4 respectively.

The common electrode layer CM is, for example, a transparent conductive layer made of a metal oxide conductive material, such as indium tin oxide, indium zinc oxide, aluminum tin oxide, aluminum zinc oxide, indium gallium zinc oxide, other suitable metal oxides, or a stacked layer of at least two of the above. The intermediate insulation layer 160 may be made of an inorganic material, an organic material or a combination thereof, wherein the inorganic material is, for example, silicon oxide, silicon nitride, silicon oxynitride or a stacked layer of at least two of the above materials; and the organic material is, for example, a polymeric material, such as a polyimide-based resin, an epoxy-based resin, an acrylic-based resin.

The first antenna A1 is disposed on the first substrate 100 and disposed corresponding to the scan lines SL1 and SL2 and the data lines DL1 and DL2. From another perspective, in this embodiment, the first antenna A1 is disposed corresponding to the pixel structures P1 to P4. For example, a routing of the first antenna A1 passes through the corresponding pixel structures (e.g., the pixel structures P1 to P4). Although the first antenna A1 is disposed corresponding to four pixel structures (i.e., the pixel structures P1 to P4), the disclosure is not limited thereto. In other embodiments, practically, according to layout design and the like of the display panel 10, the first antenna A1 may also be disposed corresponding to a different number of the pixel structures, e.g., 576 pixel structures. In addition, as shown in FIG. 2, in this embodiment, the first antenna A1 is a multiple-turn coil. However, the disclosure is not limited to the above. In other embodiments, the first antenna A1 may also be a single-turn coil.

Referring to FIG. 2 and FIG. 3 together, in this embodiment, the insulation layer 130 covers the first antenna A1, and the scan lines SL1 and SL2 are disposed on the insulation layer 130. In this embodiment, the first antenna A1 and the scan lines SL1 and SL2 may belong to different layers, and the first antenna A1 and the data lines DL1 and DL2 may belong to different layers. The insulation layer 130 may be made of an inorganic material, an organic material or a combination thereof. The inorganic material is, for example, silicon oxide, silicon nitride, silicon oxynitride or a stacked layer of at least two of the above materials. The organic material is, for example, a polymeric material, such as a polyimide-based resin, an epoxy-based resin, an acrylic-based resin.

As shown in FIG. 2 and FIG. 3, along a normal direction Z of the first substrate 100 (or may be referred to as perpendicularly projected in a direction Z of the first substrate 100), the first antenna A1 does not completely overlap with the corresponding scan lines SL1 and SL2 and the corresponding data lines DL1 and DL2. In this way, the parasitic capacitance between the first antenna A1 and the corresponding scan lines SL1 and SL2, the corresponding data lines DL1 and DL2 may be reduced. In this embodiment, along the normal direction Z of the first substrate 100, a minimum distance d1 is provided between the first antenna A1 and the scan line SL1; the minimum distance d1 is provided between the first antenna A1 and the scan line SL2; the minimum distance d1 is provided between the first antenna A1 and the data line DL1; and the minimum distance d1 is provided between the first antenna A1 and the data line DL2. However, the disclosure is not limited to the above. In other embodiments, the minimum distance d1 is provided at at least one of the locations below: between the first antenna A1 and the scan line SL1, between the first antenna A1 and the scan line SL2, between the first antenna A1 and the data line DL1, and between the first antenna A1 and the data line DL2. From another perspective, the minimum distances provided between the first antenna A1 and the scan line SL1, between the first antenna A1 and the scan line SL2, between the first antenna A1 and the data line DL1 and between the first antenna A1 and the data line DL2 may be substantially identical to or different from one another. In an embodiment, the minimum distance d1, preferably, satisfies a relationship in which d1 is equal to or greater than about 0 μm and equal to or less than about 5 μm (e.g., 0 μm≤d1≤5 μm), so as to prevent an aperture ratio from being affected.

In this embodiment, the first antenna A1 is electrically connected to the data line DL1. In this way, the first antenna A1 can transmit the pixel signal received through inductive coupling to the data line DL1. As shown in FIG. 3, in this embodiment, the data line DL1 is electrically connected to a conductive pattern Y1 via a contact window X1 disposed in the insulation layer 140, and the conductive pattern Y1 is electrically connected to the first antenna A1 via a contact window X2 disposed in the insulation layer 130. For instance, in this embodiment, the conductive pattern Y1 and the scan lines SL1 and SL2 may belong to the same layer. However, the disclosure is not limited to the above. In other embodiments, it is also possible that the conductive pattern Y1 is not disposed between the data line DL1 and the first antenna A1, and the data line DL1 and the first antenna A1 are electrically connected to each other simply via the contact windows disposed in the insulation layer 140 and the insulation layer 130.

In this embodiment, the first antenna A1 may be made of Al, Mo, Ti, Cu, other suitable materials, or an alloy of said materials, and the first antenna A1 may be a single-layer or multiple-layer structure. In this embodiment, a thickness of the first antenna A1 is between about 1 μm and about 5 μm. With the thickness of the first antenna A1 falling within such range, the first antenna A1 can have a sufficiently low resistance value.

The planarization layer OC is disposed on the second substrate 110. In this embodiment, the planarization layer OC has a recess pattern C1. For instance, as shown in FIG. 3 and FIG. 4, the recess pattern C1 can accommodate a film structure Q1 visibly protruded due to the first antenna A1, so as to prevent the film structure Q1 disposed on the first substrate 100 from pushing against the planarization layer OC disposed on the second substrate 110 and affecting a gap between the first substrate 100 and the second substrate 110. In this embodiment, although the film structure Q1 only includes a part of the intermediate insulation layer 160, the disclosure is not limited thereto. In fact, according to layout design, manufacturing process parameters for each layer and the like of the display panel 10, it is also possible that the film structure Q1 is a stacked-layer structure that includes, for example, a part of the intermediate insulation layer 160 and a part of the common electrode layer CM. From another perspective, in this embodiment, with the planarization layer OC having the recess pattern C1, the pixel array layer 102 may be made not be in contact with the planarization layer OC.

From another perspective, as shown in FIG. 3 and FIG. 4, along the normal direction Z of the first substrate 100, the recess pattern C1 completely overlaps with the first antenna A1. However, the disclosure is not limited to the above. In other embodiments, along the normal direction Z of the first substrate 100, the recess pattern C1 may also partially overlap with the first antenna A1. In addition, as shown in FIG. 4, in this embodiment, the first antenna A1 may have a substantially the same outline as the recess pattern C1, but is not limited thereto. In other embodiments, it is also possible that the first antenna A1 does not have the substantially the same shape as the recess pattern C1, an area of the recess pattern C1 is greater than that of the first antenna A1 and the recess pattern C1 can accommodate the first antenna A1.

The planarization layer OC may be made of an inorganic material, an organic material or a combination thereof. The inorganic material is, for example, silicon oxide, silicon nitride, silicon oxynitride or a stacked layer of at least two of the above materials. The organic material is, for example, a polymeric material, such as a polyimide-based resin, an epoxy-based resin, an acrylic-based resin.

The spacers PS1 are disposed on the planarization layer OC and extend to the pixel array layer 102. From another perspective, the spacers PS1 are disposed between the first substrate 100 and the second substrate 110. For instance, in this embodiment, it is preferably that the spacers PS1 can maintain a proper gap between the first substrate 100 and the second substrate 110, but is not limited thereto. In other embodiments, the spacers PS1 may also include some spacers not used for maintaining the gap between the first substrate 100 and the second substrate 110. As shown in FIG. 3, in this embodiment, the spacers PS1 extend to the pixel array layer 102 and are in contact with the pixel array layer 102 to maintain the proper gap between the first substrate 100 and the second substrate 110. For instance, a layer of the pixel array layer 102 in contact with the spacers PS1 may be one of the following examples: the intermediate insulation layer 160, a pixel electrode layer PE, the common electrode layer CM, an alignment layer (when the display medium layer 120 is a non-self-luminescent material, not illustrated), or other suitable layers. As described above, since the recess pattern C1 of the planarization layer OC can accommodate the film structure Q1 visibly protruded due to the first antenna A1 to prevent the film structure Q1 from pushing against the planarization layer OC, the spacers PS1 can function normally to maintain the proper gap between the first substrate 100 and the second substrate 110 in order to prevent display quality from being affected.

In this embodiment, the spacers PS1 may be made of, for example, a photoresist material, but the disclosure is not limited thereto. Besides, as shown in FIG. 2, in this embodiment, four spacers PS1 are disposed in the sensing unit U1. However, the disclosure is not limited to the above so long as the sensing unit U1 includes at least one spacer PS1. In addition, as shown in FIG. 2 and FIG. 3, in this embodiment, each of the spacers PS1 is correspondingly disposed at an intersection between the scan line and the data line, but the disclosure is not limited thereto. In other embodiments, the spacers PS1 may also be correspondingly disposed on the scan line or the data line.

The display medium layer 120 is disposed between the first substrate 100 and the second substrate 110. In this embodiment, the display medium layer 120 may be the non-self-luminescent material which includes, for example, a plurality of liquid crystal molecules, wherein the liquid crystal molecules may be positive liquid crystal molecules, negative liquid crystal molecules or other suitable liquid crystal molecules. In this case, the display panel 10 may be a liquid crystal display panel.

The light shielding pattern layer BM is disposed on the second substrate 110. In this embodiment, the light shielding pattern layer BM may be any light shielding pattern layer for the display panel well-known to persons of ordinary skill in the art. For example, in this embodiment, the light shielding pattern layer BM can hide elements and wirings not intended to be seen by users including, for example, the scan line SL1, the scan line SL2, the data line DL1, the data line DL2, the first antenna A1, the active element T1, the active element T2, the active element T3 and the active element T4, etc. From another perspective, in this embodiment, along the normal direction Z of the first substrate 100, the light shielding pattern layer BM may at least partially overlap with the scan line SL1, the scan line SL2, the data line DL1, the data line DL2 and the first antenna A1. The light shielding pattern layer BM may be made of a material with lower reflection, such as a black resin or a light shielding metal or alloy (e.g., Cr). In addition, as shown in FIG. 3, in this embodiment, it is exemplified that the recess pattern C1 of the planarization layer OC can, for example but not limited to, expose a part of the light shielding pattern layer BM.

The color filter patterns CF1 are disposed on the second substrate 110. In this embodiment, the color filter pattern CF1 may be any color filter pattern for the display panel well-known to persons of ordinary skill in the art. For instance, in this embodiment, the color filter patterns CF1 are respectively disposed corresponding to the pixel structures P1 to P4 and configured to achieve color screen display. In this embodiment, each color filter pattern CF1 may be a red filter pattern, a green filter pattern or a blue filter pattern, but the disclosure is not limited thereto. In addition, as shown in FIG. 3, in this embodiment, for example, it is exemplified that the recess pattern C1 of the planarization layer OC does not overlap with the color filter patterns CF1, but is not limited thereto.

Referring back to FIG. 2 and FIG. 5, the sensing unit U2 includes a pixel array layer 104, a first antenna A2, the planarization layer OC, a plurality of spacers PS2 and the display medium layer 120. Based on the above description, it can be known that, in this embodiment, the planarization layer OC is formed on the second substrate 110, and the sensing unit U1 and the sensing unit U2 respectively include a part of the planarization layer OC; and the display medium layer 120 is formed between the first substrate 100 and the second substrate 110, and the sensing unit U1 and the sensing unit U2 respectively include a part of the display medium layer 120. In addition, the sensing unit U2 may further include the light shielding pattern layer BM, a plurality of color filter patterns CF2, the insulation layer 130, the insulation layer 140, the protection layer 150 and the intermediate insulation layer 160. Based on the above description, it can be known that, in this embodiment, the light shielding pattern layer BM is formed on the second substrate 110, and the sensing unit U1 and the sensing unit U2 respectively include a part of the light shielding pattern layer BM; the insulation layer 130 is formed on the first substrate 100, and the sensing unit U1 and the sensing unit U2 respectively include a part of the insulation layer 130; and the insulation layer 140, the protection layer 150 and the intermediate insulation layer 160 are all formed on the first substrate 100, and the pixel array layer 102 and the pixel array layer 104 both include a part of the insulation layer 130, a part of the protection layer 150 and a part of the intermediate insulation layer 160.

The pixel array layer 104 is disposed on the first substrate 100. In this embodiment, the pixel array layer 104 includes a scan line SL3, a scan line SL4, a data line DL1′, a data line DL2′ and a plurality of pixel structures P5 to P8. In this embodiment, the scan line SL1, the scan line SL2, the scan line SL3 and the scan line SL4 are arranged in sequence along an extending direction of the data line DL1, the data line DL2, the data line DL1′ and the data line DL2′. From another perspective, in this embodiment, the pixel array layer 102 and the pixel array layer 104 may be disposed adjacent to each other on the first substrate 100 along the extending direction of the data line DL1, the data line DL2, the data line DL1′ and the data line DL2′ (which may be referred as being arranged along a column direction), but is not limited thereto. In some embodiments, the pixel array layer 102 and the pixel array layer 104 may also be disposed adjacent to each other on the first substrate 100 along an extending direction of the scan line SL, the scan line SL2, the scan line SL3 and the scan line SL4 (which may be referred to as being arranged along a row direction).

The extending direction of the scan lines SL3 and SL4 is different from the extending direction of the data lines DL1′ and DL2′. Preferably, the extending direction of the scan lines SL3 and SL4 interlaces with (e.g., substantially perpendicular to) the extending direction of the data lines DL1′ and DL2′, but is not limited thereto. Further, in this embodiment, the scan lines SL3 and SL4 and the data lines DL1′ and DL2′ may be located in different layers, and the insulation layer 140 may be interposed between the scan lines SL3 and SL4 and the data lines DL1′ and DL2′. The scan lines SL3 and SL4 and the data lines DL1′ and DL2′ are generally made of a metal material considering conductivity. However, the disclosure is not limited to the above. According to other embodiments, the scan lines SL3 and SL4 and the data lines DL1′ and DL2′ may also be made of, for example, other conductive materials such as an alloy, a nitride of said metal material, an oxide of said metal material, an oxynitride of said metal material, other suitable conductive materials, or a stacked layer of said metal material and said other conductive materials. In addition, in this embodiment, as shown in FIG. 2, the data line DL1′ and the data line DL1 are connected to each other as one, and the data line DL2′ and the data line DL2 are connected to each other as one.

In this embodiment, the pixel structure P5 includes an active element T5, a first electrode PE5 and a second electrode CM5; the pixel structure P6 includes an active element T6, a first electrode PE6 and a second electrode CM6; the pixel structure P7 includes an active element T7, a first electrode PE7 and a second electrode CM7; and the pixel structure P8 includes an active element T8, a first electrode PE8 and a second electrode CM8.

In this embodiment, the active element T5 is electrically connected to the scan line SL3 and the data line DL1′; the active element T6 is electrically connected to the scan line SL3 and the data line DL2′; the active element T7 is electrically connected to the scan line SL4 and the data line DL1′; and the active element T8 is electrically connected to the scan line SL4 and the data line DL2′. In other words, in this embodiment, the pixel structure P5 is electrically connected to the scan line SL3 and the data line DL1′; the pixel structure P6 is electrically connected to the scan line SL3 and the data line DL2′; the pixel structure P7 is electrically connected to the scan line SL4 and the data line DL1′; and the pixel structure P8 is electrically connected to the scan line SL4 and the data line DL2′. Therefore, it can be known that the active element (e.g., the active element T5) of the pixel structure (e.g., the pixel structure P5) is electrically connected to the corresponding scan line (e.g., the scan line SL3) and the corresponding data line (e.g., the data line DL1′).

For instance, in this embodiment, the active element T5 includes a gate G5, a channel layer CH5 disposed corresponding to the gate G5, and a drain D5 and source S5 electrically connected to two sides of the channel layer CH5; the active element T6 includes a gate G6, a channel layer CH6 disposed corresponding to the gate G6, and a drain D6 and source S6 electrically connected to two sides of the channel layer CH6; the active element T7 includes a gate G7, a channel layer CH7 disposed corresponding to the gate G7, and a drain D7 and source S7 electrically connected to two sides of the channel layer CH7; and the active element T8 includes a gate G8, a channel layer CH8 disposed corresponding to the gate G8, and a drain D8 and source S8 electrically connected to two sides of the channel layer CH8.

In this embodiment, a partial region of the scan line SL3 is used as the gate G5 and the gate G6, and a partial region of the scan line SL4 is used as the gate G7 and the gate G8. In other words, the gate G5, the gate G6 and the scan line SL3 are electrically connected to each other, and the gate G7, the gate G8 and the scan line SL4 are electrically connected to each other. From another perspective, the partial region of the scan line used as the gates includes a part extended from the scan line used as the gates or a part of the scan line itself used as the gates. In addition, in this embodiment, the source S5, the source S7 and the data line DL1′ are a continuous conductive pattern, and the source S6, the source S8 and the data line DL2′ are a continuous conductive pattern. In other words, the source S5, the source S7 and the data line DL1′ are electrically connected to each other, and the source S6, the source S8 and the data line DL2′ are electrically connected to each other. From another perspective, in this embodiment, when the control signal is input to the scan line SL3, the scan line SL3, the gate G5 and the gate G6 are electrically connected; when the control signal is input to the scan line SL4, the scan line SL4, the gate G7 and the gate G8 are electrically connected; when the pixel signal is input to the data line DL1′, the data line DL1′, the source S5 and the source S7 are electrically connected; and when the pixel signal is input to the data line DL2′, the data line DL2′, the source S6 and the source S8 are electrically connected.

The channel layer CH5 is located above the gate G5; the channel layer CH6 is located above the gate G6; the channel layer CH7 is located above the gate G7; and the channel layer CH8 is located above the gate G8. The source S5 and the drain D5 are located above the channel layer CH5; the source S6 and the drain D6 are located above the channel layer CH6; the source S7 and the drain D7 are located above the channel layer CH7; and the source S8 and the drain D8 are located above the channel layer CH8. For instance, in this embodiment, at least one of the active element T5, the active element T6, the active element T7 and the active element T8 is referred to as the bottom-gate thin film transistor as an example, but the disclosure is not limited thereto.

In other embodiments, at least one of the active element T5, the active element T6, the active element T7 and the active element T8 may also be the top-gate thin film transistor, the 3D thin film transistor or other suitable thin film transistors.

In this embodiment, the insulation layer 140 further covers the gate G5 of the active element T5, the gate G6 of the active element T6, the gate G7 of the active element T7, and the gate G8 of the active element T8. In addition, the protection layer 150 may further cover the active element T5, the active element T6, the active element T7 and the active element T8.

In this embodiment, the first electrode PE5 is electrically connected to the drain D5 of the active element T5 via a contact window H5; the first electrode PE6 is electrically connected to the drain D6 of the active element T6 via a contact window H6; the first electrode PE7 is electrically connected to the drain D7 of the active element T7 via a contact window H7; and the first electrode PE8 is electrically connected to the drain D8 of the active element T8 via a contact window H8. From another perspective, in this embodiment, the first electrode PE5, the first electrode PE6, the first electrode PE7 and the first electrode PE8 may be used as the pixel electrodes of the pixel structure P5, the pixel structure P6, the pixel structure P7 and the pixel structure P8 respectively.

In this embodiment, materials of the first electrode PE5, the first electrode PE6, the first electrode PE7 and the first electrode PE8 may include a metal oxide conductive material, such as indium tin oxide, indium zinc oxide, aluminum tin oxide, aluminum zinc oxide, indium gallium zinc oxide, other suitable oxides, or a stacked layer of at least two of the above. In addition, in this embodiment, the first electrode PE5, the first electrode PE6, the first electrode PE7 and the first electrode PE8 respectively include a plurality of stripe electrode patterns.

In this embodiment, the second electrode CM5 is disposed corresponding to the first electrode PE5; the second electrode CM6 is disposed corresponding to the first electrode PE6; the second electrode CM7 is disposed corresponding to the first electrode PE7; and the second electrode CM8 is disposed corresponding to the first electrode PE8. For instance, in this embodiment, the second electrode CM5, the second electrode CM6, the second electrode CM7 and the second electrode CM8 are connected to each other to form a part of the common electrode layer CM. In this embodiment, the second electrodes CM1 to CM4 in the pixel array layer 102 and the second electrode CM5 to CM8 in the pixel array layer 104 are connected to each other. Also, a part of the common electrode layer CM corresponding to the first electrode PE5 is used as the second electrode CM5 of the pixel structure P5; a part of the common electrode layer CM corresponding to the first electrode PE6 is used as the second electrode CM6 of the pixel structure P6; a part of the common electrode layer CM corresponding to the first electrode PE7 is used as the second electrode CM7 of the pixel structure P7; and a part of the common electrode layer CM corresponding to the first electrode PE8 is used as the second electrode CM8 of the pixel structure P8. From another perspective, in this embodiment, the second electrode CM5, the second electrode CM6, the second electrode CM7 and the second electrode CM8 are used as the common electrodes of the pixel structure P5, the pixel structure P6, the pixel structure P7 and the pixel structure P8 respectively. In other embodiments, the second electrode CM5, the second electrode CM6, the second electrode CM7 and the second electrode CM8 are used as the pixel electrodes of the pixel structure P5, the pixel structure P6, the pixel structure P7 and pixel structure P8 respectively, spaced apart from each other, and electrically connected to the corresponding active element; and the first electrode PE5, the first electrode PE6, the first electrode PE7 and the first electrode PE8 are used as the common electrodes of the pixel structure P5, the pixel structure P6, the pixel structure P7 and the pixel structure P8 respectively.

In this embodiment, the intermediate insulation layer 160 is further disposed between the common electrode layer CM and the first electrode PE5, the first electrode PE6, the first electrode PE7, the first electrode PE8, such that the common electrode layer CM and the first electrode PE5, the first electrode PE6, the first electrode PE7, the first electrode PE8 are structurally separated from each other. In addition, with reference to FIG. 2 and FIG. 5, the first electrode PE5, the first electrode PE6, the first electrode PE7 and the first electrode PE8 are disposed above the intermediate insulation layer 160, and the common electrode layer CM is disposed under the intermediate insulation layer 160. From another perspective, in this embodiment, the second electrode CM5, the second electrode CM6, the second electrode CM7 and the second electrode CM8 are correspondingly disposed under the first electrode PE5, the first electrode PE6, the first electrode PE7 and the first electrode PE8 respectively. In other embodiments, the second electrode CM5, the second electrode CM6, the second electrode CM7, and the second electrode CM8 are correspondingly disposed above the first electrode PE5, the first electrode PE6, the first electrode PE7 and the first electrode PE8 respectively, wherein the second electrode CM5, the second electrode CM6, the second electrode CM7 and the second electrode CM8 are used as the pixel electrodes of the pixel structure P5, the pixel structure P6, the pixel structure P7 and the pixel structure P8 respectively, spaced apart from each other, and electrically connected to the corresponding active element; and the first electrode PE5, the first electrode PE6, the first electrode PE7 and the first electrode PE8 are used as the common electrodes of the pixel structure P5, the pixel structure P6, the pixel structure P7 and the pixel structure P8 respectively.

It is worth noting that, during operations of the display panel 10, the pixel electrodes (i.e., the first electrodes PE1 to PE8) and the common electrodes (the second electrodes CM1 to CM8) are configured with different operating voltages. Accordingly, a fringe electric field may be formed between the pixel electrodes and the common electrodes to drive the display medium layer 120 for producing display function. In this embodiment, the display panel 10 may be a fringe field switching (FFS) display panel. However, the disclosure is not limited to the above. In other embodiments, the pixel electrodes and the common electrodes may both include the stripe electrode patterns and belong to the same layer. In this case, the display panel 10 may also be an In-Plane switching (IPS) display panel.

The first antenna A2 is disposed on the first substrate 100 and disposed corresponding to the scan lines SL3 and SL4 and the data lines DL1′ and DL2′. From another perspective, in this embodiment, the first antenna A2 is disposed corresponding to the pixel structures P5 to P8. For example, a routing of the first antenna A2 passes through the corresponding pixel structures (e.g., the pixel structures P5 to P8). Although the first antenna A2 is disposed corresponding to four pixel structures (i.e., the pixel structures P5 to P8), the disclosure is not limited thereto. In other embodiments, practically, according to layout design and the like of the display panel 10, the first antenna A2 may also be disposed corresponding to a different number of the pixel structures, e.g., 576 pixel structures. In addition, as shown in FIG. 2, in this embodiment, the first antenna A2 is the multiple-turn coil. However, the disclosure is not limited to the above. In other embodiments, the first antenna A2 may also be the single-turn coil.

Referring to FIG. 2 and FIG. 5 together, in this embodiment, the insulation layer 130 further covers the first antenna A2, and the scan lines SL3 and SL4 are disposed on the insulation layer 130. In this embodiment, the first antenna A2 and the scan lines SL3 and SL4 may belong to different layers, and the first antenna A2 and the data lines DL1′ and DL2′ may belong to different layers.

As shown in FIG. 2 and FIG. 5, along the normal direction Z of the first substrate 100, the first antenna A2 does not completely overlap with the corresponding scan lines SL3 and SL4 and the corresponding data lines DL1′ and DL2′. In this way, the parasitic capacitance between the first antenna A2 and the corresponding scan lines SL3 and SL4, the corresponding data lines DL1′ and DL2′ may be reduced. In this embodiment, along the normal direction Z of the first substrate 100, a minimum distance d2 is provided between the first antenna A2 and the scan line SL3; the minimum distance d2 is provided between the first antenna A2 and the scan line SL4; the minimum distance d2 is provided between the first antenna A2 and the data line DL1′; and the minimum distance d2 is provided between the first antenna A2 and the data line DL2′. However, the disclosure is not limited to the above. In other embodiments, the minimum distance d2 is provided at at least one of the locations below: between the first antenna A2 and the scan line SL3, between the first antenna A2 and the scan line SL4, between the first antenna A2 and the data line DL1′, and between the first antenna A2 and the data line DL2′. From another perspective, the minimum distances provided between the first antenna A2 and the scan line SL3, between the first antenna A2 and the scan line SL4, between the first antenna A2 and the data line DL1′ and between the first antenna A2 and the data line DL2′ may be substantially identical to or different from one another. In an embodiment, the minimum distance d2, preferably, satisfies a relationship in which d2 is equal to or greater than about 0 μm and equal to or less than about 5 μm (e.g., 0 μm≤d2≤5 μm), so as to prevent the aperture ratio from being affected.

In this embodiment, the first antenna A2 is electrically connected to the data line DL2′. Accordingly, the first antenna A2 can transmit the pixel signal received through inductive coupling to the data line DL2′. As described above, the data line DL1′ and the data line DL1 are connected to each other as one, and the data line DL2′ and the data line DL2 are connected to each other as one. Based on that, in this embodiment, the first antenna A1 in the sensing unit U1 and the first antenna A2 in the sensing unit U2 are electrically connected to different data lines. Therefore, the first antenna A1 may be regarded as being electrically connected to the data line DL1, whereas the first antenna A2 may be regarded as being electrically connected to the data line DL2.

In addition, as shown in FIG. 5, in this embodiment, the data line DL2′ is electrically connected to a conductive pattern Y2 via a contact window X3 disposed in the insulation layer 140, and the conductive pattern Y2 is electrically connected to the first antenna A1 via a contact window X4 disposed in the insulation layer 130. For instance, in this embodiment, the conductive pattern Y2 and the scan lines SL3 and SL4 may belong to the same layer. However, the disclosure is not limited to the above. In other embodiments, it is also possible that the conductive pattern Y2 is not disposed between the data line DL2′ and the first antenna A2, and the data line DL2′ and the first antenna A2 are electrically connected to each other simply via the contact windows disposed in the insulation layer 140 and the insulation layer 130.

In this embodiment, the first antenna A2 may be made of Al, Mo, Ti, Cu, other suitable materials, or an alloy of said materials, and the first antenna A2 may be a single-layer or multiple-layer structure. In this embodiment, a thickness of the first antenna A2 is between about 1 μm and about 5 μm. With the thickness of the first antenna A2 falling within such range, the first antenna A2 can have a sufficiently low resistance value.

In this embodiment, the planarization layer OC has a recess pattern C2. Although FIG. 4 illustrates only the disposition relationship of the first antenna A1 and the recess pattern C1, persons of ordinary skill in the art should be able to understand a disposition relationship between the first antenna A2 and the recess pattern C2 according to the description for FIG. 3 and FIG. 4. For instance, according to the description for FIG. 3 and FIG. 4 and FIG. 5, it can be known that the recess pattern C2 is configured to accommodate a film structure Q2 visibly protruded due to the first antenna A2, so as to prevent the film structure Q2 disposed on the first substrate 100 from pushing against the planarization layer OC disposed on the second substrate 110 and affecting the gap between the first substrate 100 and the second substrate 110. Further, in this embodiment, although the film structure Q2 only includes a part of the intermediate insulation layer 160, the disclosure is not limited thereto. In fact, according to layout design, manufacturing process parameters for each layer and the like of the display panel 10, the film structure Q2 may also be a stacked-layer structure that includes, for example, a part of the intermediate insulation layer 160 and a part of the common electrode layer CM. From another perspective, in this embodiment, with the planarization layer OC having the recess pattern C2, the pixel array layer 104 may be made not be in contact with the planarization layer OC.

From another perspective, according to the description for FIG. 3 and FIG. 4 and FIG. 5, it can be known that, along the normal direction Z of the first substrate 100, the recess pattern C2 completely overlaps with the first antenna A2. However, the disclosure is not limited to the above. In other embodiments, along the normal direction Z of the first substrate 100, the recess pattern C2 may also partially overlap with the first antenna A2. In addition, according to the description for FIG. 4, in this embodiment, the first antenna A2 may have a substantially the same outline as the recess pattern C2, but is not limited thereto. In other embodiments, it is also possible that the first antenna A2 does not have the substantially the same shape as the recess pattern C2, an area of the recess pattern C2 is greater than that of the first antenna A2 and the recess pattern C2 can accommodate the first antenna A2.

The spacers PS2 are disposed on the planarization layer OC and extend to the pixel array layer 104. In other words, the spacers PS2 are disposed between the first substrate 100 and the second substrate 110. For instance, in this embodiment, it is preferably that the spacers PS2 can maintain a proper gap between the first substrate 100 and the second substrate 110, but is not limited thereto. In other embodiments, the spacers PS2 may also include some spacers not used for maintaining the gap between the first substrate 100 and the second substrate 110. As shown in FIG. 5, in this embodiment, the spacers PS2 extend to the pixel array layer 104 and are in contact with the pixel array layer 104 to maintain the proper gap between the first substrate 100 and the second substrate 110. For instance, a layer of the pixel array layer 104 in contact with the spacers PS2 may be at least one of the following examples: the intermediate insulation layer 160, the pixel electrode layer PE, the common electrode layer CM, the alignment layer (when the display medium layer 120 is the non-self-luminescent material, not illustrated), or other suitable layers. As described above, since the recess pattern C2 of the planarization layer OC can accommodate the film structure Q2 visibly protruded due to the first antenna A2 to prevent the film structure Q2 from pushing against the planarization layer OC, the spacers PS2 can function normally to maintain the proper gap between the first substrate 100 and the second substrate 110 in order to prevent display quality from being affected.

In this embodiment, the spacers PS2 may be made of, for example, a photoresist material, but the disclosure is not limited thereto. Besides, as shown in FIG. 2, in this embodiment, four spacers PS2 are disposed in the sensing unit U2. However, the disclosure is not limited to the above so long as the sensing unit U2 includes at least one spacer PS2. In addition, as shown in FIG. 2 and FIG. 5, in this embodiment, each of the spacers PS2 is correspondingly disposed at an intersection between the scan line and the data line, but the disclosure is not limited thereto. In other embodiments, the spacers PS2 may also be correspondingly disposed on the scan line or the data line.

In this embodiment, the light shielding pattern layer BM corresponding to the sensing unit U2 may be used to hide elements and wirings such as the scan line SL3, the scan line SL4, the data line DL1′, the data line DL2′, the first antenna A2, the active element T5, the active element T6, the active element T7 and the active element T8 from being seen by users. From another perspective, in this embodiment, along the normal direction Z of the first substrate 100, the light shielding pattern layer BM may at least partially overlap with the scan line SL3, the scan line SL4, the data line DL1′, the data line DL2′ and the first antenna A2. In addition, as shown in FIG. 5, in this embodiment, it is exemplified that the recess pattern C2 of the planarization layer OC can, for example but not limited to, expose a part of the light shielding pattern layer BM.

The color filter patterns CF2 are disposed on the second substrate 110. In this embodiment, the color filter pattern CF2 may be any color filter pattern for the display panel well-known to persons of ordinary skill in the art. For instance, in this embodiment, the color filter patterns CF2 are respectively disposed corresponding to the pixel structures P5 to P8 and configured to achieve color screen display. In this embodiment, each color filter pattern CF2 may be a red filter pattern, a green filter pattern or a blue filter pattern, but the disclosure is not limited thereto. In addition, as shown in FIG. 5, in this embodiment, for example, it is exemplified that the recess pattern C2 of the planarization layer OC does not overlap with the color filter patterns CF2, but is not limited thereto.

Referring back to FIG. 1, the circuit board 20 is disposed under the display panel 10. In this embodiment, the circuit board 20 has a plurality of second antennas B. In this embodiment, the second antenna B is the multiple-turn coil. However, the disclosure is not limited to the above. In other embodiments, the second antenna B may also be the single-turn coil. In this embodiment, the second antenna B may be made of Al, Mo, Ti, Cu, other suitable materials, or an alloy of said materials, and the second antenna B may be a single-layer or multiple-layer structure. Further, in this embodiment, a thickness of the second antenna B is between about 1 μm and about 5 μm. With the thickness of the second antenna B falling within such range, the second antenna B can have a sufficiently low resistance value.

As shown in FIG. 1, in this embodiment, the second antennas B are disposed corresponding to the sensing units U. For instance, according to the description for the sensing unit U1 and the sensing unit U2, persons of ordinary skill in the art should be able to understand that one sensing unit U includes one first antenna. From another perspective, in this embodiment, the second antennas B are respectively disposed corresponding to the first antennas A1 and A2 in the sensing units U. For instance, one of the second antennas B is disposed corresponding to the first antenna A1 in the sensing unit U1, and another one of the second antennas B is disposed corresponding to the first antenna A2 in the sensing unit U2.

It is worth noting that, in this embodiment, by disposing the second antennas B in the circuit board 20 and disposing the first antennas (including the first antennas A1 and A2) in the display panel 10 for the display device 1, the pixel signal may be transmitted through inductive coupling from the second antenna B to the corresponding first antenna, so as to achieve transmitting the pixel signal through wireless transmission. In this embodiment, the second antennas B in the circuit board 20 may be regarded as a transmitter in wireless transmission, and the first antennas (including the first antennas A1 and A2) in the display panel 10 may be regarded as a receiver in wireless transmission. As described above, when the first antenna (e.g., the first antenna A1) receives the pixel signal transmitted through inductive coupling from the corresponding second antenna B, the pixel signal may be transmitted to the data lines DL1 and DL1′ electrically connected to the first antenna (e.g., the first antenna A1); and when the first antenna (e.g., the first antenna A2) receives the pixel signal transmitted through inductive coupling from the corresponding second antenna B, the pixel signal may be transmitted to the data lines DL2 and DL2′ electrically connected to the first antenna (e.g., the first antenna A2).

Referring back to FIG. 1, the backlight module 30 is disposed under the display panel 10. In this embodiment, the backlight module 30 is disposed between the display panel 10 and the circuit board 20. Further, in this embodiment, the backlight module 30 may be any backlight module for the display panel well-known to persons of ordinary skill in the art. Specifically, in this embodiment, the backlight module 30 may be configured to provide a plane light source, a spot light source, a plasma panel light source, a carbon nanotube light source, other light sources, or a combination of the above, wherein a type of the light source used by the plane light source may, for example, include: a cold cathode fluorescent tube, a hot cathode fluorescent tube, an external electrode fluorescent tube, a flat fluorescent tube, other tubes, or a combination thereof. The point light source may be, for example, an inorganic light-emitting diode, an organic micro-molecular phosphorescent/fluorescent light-emitting diode, an organic macromolecular phosphorescent/fluorescent light-emitting diode, other diodes, or a combination thereof.

Based on content in the embodiments related to FIG. 1 to FIG. 5, with the sensing unit U1 including the first antenna A1 electrically connected to the data line DL1, the sensing unit U2 including the first antenna A2 electrically connected to the data line DL2′, the planarization layer OC having the recess pattern C1 that at least partially overlaps with the first antenna A1 along the normal direction Z and the recess pattern C2 that at least partially overlaps with the first antenna A2 along the normal direction Z, and the circuit board 20 having the second antennas B disposed corresponding to the first antennas A1 to A2, the display device 1 can transmit the pixel signal through wireless transmission and prevent the gap between the first substrate 100 and the second substrate 110 from being affected, so as to provide favorable display quality.

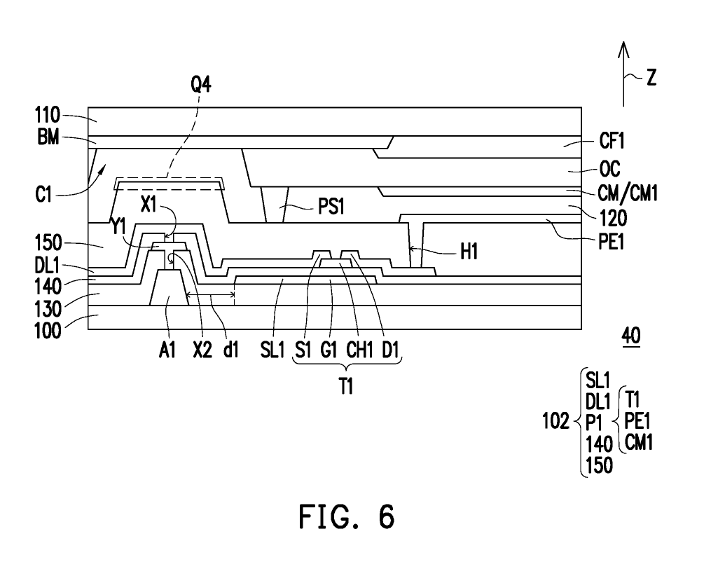

In addition, in the embodiments of FIG. 1 to FIG. 5, the common electrode layer CM in the display panel 10 is disposed on the first substrate 100, but the disclosure is not limited thereto. In other embodiments, the common electrode layer CM may also be disposed on the second substrate 110. Other modifications are described in detail below with reference to FIG. 6. It should be noted that the reference numerals and a part of the contents in the previous embodiment are used in the following embodiments, in which identical or similar reference numerals indicate identical or similar elements, and repeated description of the same technical contents is omitted. The omitted part of the description can refer to the foregoing embodiment, which is not repeated in the following embodiments.

FIG. 6 is a schematic partial cross-sectional view of a display panel according to another embodiment of the disclosure. It should be noted that, the cross-sectional position of FIG. 6 corresponds to the position of the section line I-I′ of FIG. 2, and FIG. 6 only illustrates a partial structure of the sensing unit U1 in a display panel 40. However, according to content in the embodiments of FIG. 1 to FIG. 5, persons of ordinary skill in the art should be able to understand overall structure or layout of the display panel 40, as well as overall structure or layout of the display device including the display panel 40, the circuit board 20 and the backlight module 30 included when the display medium layer 120 is the non-self-luminescent material.

Referring to FIG. 6 and FIG. 3 together, the display panel 40 of FIG. 6 is similar to the display panel 10 of FIG. 3 and can refer to the related description above. Thus, only the difference between the two is described below.

With reference to FIG. 6, in this embodiment, the first electrode PE1 is electrically connected to the drain D1 of the active element T1 via the contact window H1, wherein the contact window H1 is disposed in the protection layer 150. In this embodiment, a counter shape of the first electrode PE1 may be a blocky pattern. However, the disclosure is not limited to the above. In other embodiments, the counter shape of the first electrode PE1 may be a fishbone pattern or other suitable patterns (e.g., the counter shape of the first electrode PE1 is still the blocky pattern with presence of the fishbone pattern inside the first electrode PE1, or the counter shape of the first electrode PE1 is still the blocky pattern with presence of a cross pattern or other suitable patterns inside the first electrode PE1). In other word, said patterns may include an opening or a stripe.

In this embodiment, the second electrode CM1 disposed corresponding to the first electrode PE1 is disposed on the planarization layer OC. In this embodiment, a part of the common electrode layer CM corresponding to the first electrode PE1 is used as the second electrode CM1 of the pixel structure P1. During operations of the display panel 40, the first electrode PE1 and the second electrode CM1 are configured with different operating voltages. Accordingly, a vertical electric field may be formed between the first electrode PE1 and the second electrode CM1 to drive the display medium layer 120 for producing display function.

In this embodiment, the recess pattern C1 is configured to accommodate a film structure Q4 visibly protruded due to the first antenna A1, so as to prevent display quality from being affected by the spacers PS1 that failed to function normally for maintaining the proper gap between the first substrate 100 and the second substrate 110 when the film structure Q4 disposed on the first substrate 100 pushes against the planarization layer OC disposed on the second substrate 110. In this embodiment, although the film structure Q4 includes a part of the protection layer 150, the disclosure is not limited thereto. In fact, according to layout design, manufacturing process parameters for each layer and the like of the display panel 40, the film structure Q4 may also be a stacked-layer structure.

Based on content of FIG. 6 and content in the embodiments related to FIG. 1 to FIG. 5, with the sensing unit U1 including the first antenna A1 electrically connected to the data line DL1, the sensing unit U2 including the first antenna A2 electrically connected to the data line DL2′, the planarization layer OC having the recess pattern C1 that at least partially overlaps with the first antenna A1 along the normal direction Z and the recess pattern C2 that at least partially overlaps with the first antenna A2 along the normal direction Z, and the circuit board 20 having the second antennas B disposed corresponding to the first antennas A1 to A2, the display device (which includes the display panel 40, the circuit board 20 and the backlight module 30 included when the display medium layer 120 is the non-self-luminescent material) can transmit the pixel signal through wireless transmission and prevent the gap between the first substrate 100 and the second substrate 110 from being affected, so as to provide favorable display quality.

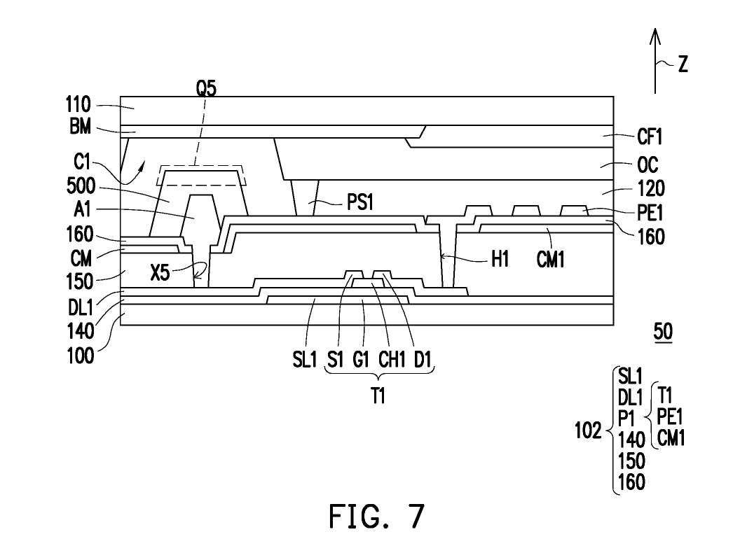

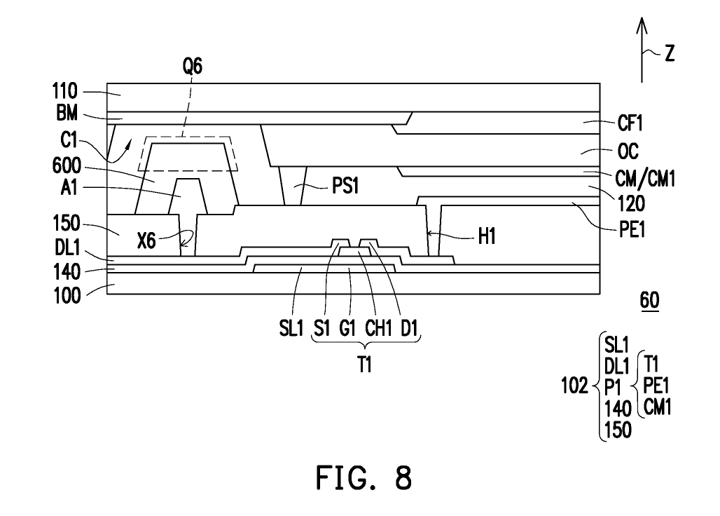

In addition, in the embodiments of FIG. 1 to FIG. 5 and the embodiment of FIG. 6, the first antennas A1 and A2 of the display panel 10 and the display panel 40 are formed before the scan line SL1, the scan line SL2, the scan line SL3, the scan line SL4, the data line DL1, the data line DL2, the data line DL1′, the data line DL2′ are formed, but the disclosure is not limited thereto. In other embodiments, the first antennas A1 and A2 may also be formed after the scan line SL, the scan line SL2, the scan line SL3, the scan line SL4, the data line DL1, the data line DL2, the data line DL1′, the data line DL2′ are formed. Other modifications are described in detail below with reference to FIGS. 7 and 8. It should be noted that the reference numerals and a part of the contents in the previous embodiment are used in the following embodiments, in which identical or similar reference numerals indicate identical or similar elements, and repeated description of the same technical contents is omitted. The omitted part of the description can refer to the foregoing embodiment, which is not repeated in the following embodiments.

FIG. 7 is a schematic partial cross-sectional view of a display panel according to another embodiment of the disclosure. It should be noted that, the cross-sectional position of FIG. 7 corresponds to the position of the section line I-I′ of FIG. 2, and FIG. 7 only illustrates a partial structure of the sensing unit U1 in a display panel 50. However, according to content in the embodiments of FIG. 1 to FIG. 5, persons of ordinary skill in the art should be able to understand overall structure or layout of the display panel 50, as well as overall structure or layout of the display device including the display panel 50, the circuit board 20 and the backlight module 30 included when the display medium layer 120 is the non-self-luminescent material.

Referring to FIG. 7 and FIG. 3 together, the display panel 50 of FIG. 7 is similar to the display panel 10 of FIG. 3 and can refer to the related description above. Thus, only the difference between the two is described below.

With reference to FIG. 7, in this embodiment, the first antenna A1 is disposed on the intermediate insulation layer 160, and is electrically connected to the data line DL1 via a contact window X5, wherein the contact window X5 is disposed in the intermediate insulation layer 160 and the protection layer 150.

In this embodiment, an insulation layer 500 covers the first antenna A1 to provide insulation and protection functions. As shown in FIG. 7, the insulation layer 500 is disposed corresponding to the first antenna A1. Therefore, according to content in the embodiments of FIG. 1 to FIG. 5, persons of ordinary skill in the art should be able to understand that the insulation layer 500 includes patterned insulation patterns separated from each other and corresponding to the first antennas A1 and A2.

In this embodiment, the recess pattern C1 is configured to accommodate a film structure Q5 visibly protruded due to the first antenna A1, so as to prevent display quality from being affected by the spacers PS1 that failed to function normally for maintaining the proper gap between the first substrate 100 and the second substrate 110 when the film structure Q5 disposed on the first substrate 100 pushes against the planarization layer OC disposed on the second substrate 110. In this embodiment, although the film structure Q5 includes a part of the insulation layer 500, the disclosure is not limited thereto. In fact, according to layout design, manufacturing process parameters for each layer and the like of the display panel 50, the film structure Q5 may also be a stacked-layer structure.

Based on content of FIG. 7 and content in the embodiments related to FIG. 1 to FIG. 5, with the sensing unit U1 including the first antenna A1 electrically connected to the data line DL1, the sensing unit U2 including the first antenna A2 electrically connected to the data line DL2′, the planarization layer OC having the recess pattern C1 that at least partially overlaps with the first antenna A1 along the normal direction Z and the recess pattern C2 that at least partially overlaps with the first antenna A2 along the normal direction Z, and the circuit board 20 having the second antennas B disposed corresponding to the first antennas A1 to A2, the display device (which includes the display panel 50, the circuit board 20 and the backlight module 30 included when the display medium layer 120 is the non-self-luminescent material) can transmit the pixel signal through wireless transmission and prevent the gap between the first substrate 100 and the second substrate 110 from being affected, so as to provide favorable display quality.

FIG. 8 is a schematic partial cross-sectional view of a display panel according to another embodiment of the disclosure. It should be noted that, the cross-sectional position of FIG. 8 corresponds to the position of the section line I-I′ of FIG. 2, and FIG. 8 only illustrates a partial structure of the sensing unit U1 in a display panel 60. However, according to content in the embodiments of FIG. 1 to FIG. 5, persons of ordinary skill in the art should be able to understand overall structure or layout of the display panel 60, as well as overall structure or layout of the display device including the display panel 60, the circuit board 20 and the backlight module 30 included when the display medium layer 120 is the non-self-luminescent material.

Referring to FIG. 8 and FIG. 6 together, the display panel 70 of FIG. 8 is similar to the display panel 40 of FIG. 6 and can refer to the related description above. Thus, only the difference between the two is described below.

With reference to FIG. 8, in this embodiment, the first antenna A1 is disposed on the protection layer 150, and electrically connected to the data line DL1 via a contact window X6, wherein the contact window X6 is disposed in the protection layer 150.

In this embodiment, an insulation layer 600 covers the first antenna A1 to provide insulation and protection functions. As shown in FIG. 8, the insulation layer 600 is disposed corresponding to the first antenna A1. Therefore, according to content in the embodiments of FIG. 1 to FIG. 5, persons of ordinary skill in the art should be able to understand that the insulation layer 600 includes patterned insulation patterns separated from each other and corresponding to the first antennas A1 and A2.

In this embodiment, the recess pattern C1 is configured to accommodate a film structure Q6 visibly protruded due to the first antenna A1, so as to prevent display quality from being affected by the spacers PS1 that failed to function normally for maintaining the proper gap between the first substrate 100 and the second substrate 110 when the film structure Q6 disposed on the first substrate 100 pushes against the planarization layer OC disposed on the second substrate 110. In this embodiment, although the film structure Q6 includes a part of the insulation layer 600, the disclosure is not limited thereto. In fact, according to layout design, manufacturing process parameters for each layer and the like of the display panel 60, the film structure Q6 may also be a stacked-layer structure.

Based on content of FIG. 6 and FIG. 8 and content in the embodiments related to FIG. 1 to FIG. 5, with the sensing unit U1 including the first antenna A1 electrically connected to the data line DL1, the sensing unit U2 including the first antenna A2 electrically connected to the data line DL2′, the planarization layer OC having the recess pattern C1 that at least partially overlaps with the first antenna A1 along the normal direction Z and the recess pattern C2 that at least partially overlaps with the first antenna A2 along the normal direction Z, and the circuit board 20 having the second antennas B disposed corresponding to the first antennas A1 to A2, the display device (which includes the display panel 60, the circuit board 20 and the backlight module 30 included when the display medium layer 120 is the non-self-luminescent material) can transmit the pixel signal through wireless transmission and prevent the gap between the first substrate 100 and the second substrate 110 from being affected, so as to provide favorable display quality.

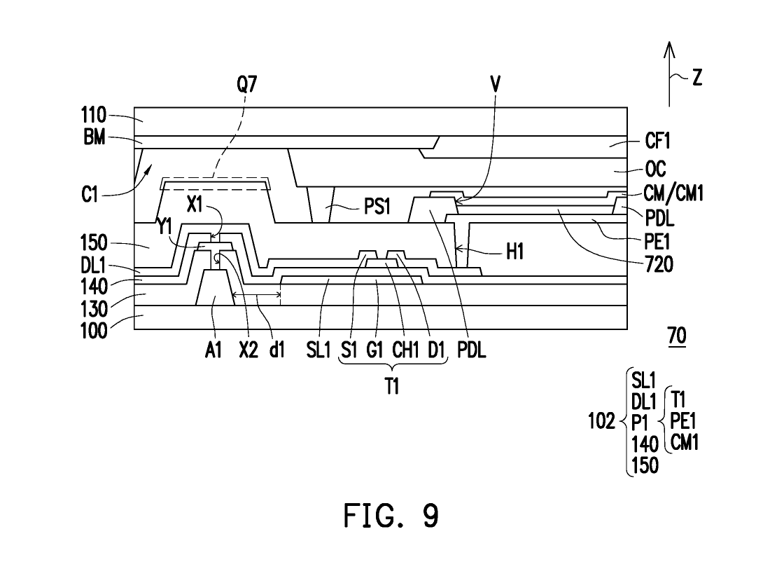

In addition, in the embodiments of FIG. 1 to FIG. 5, the display medium layer 120 includes the liquid crystal molecules, but the disclosure is not limited thereto. In other embodiments, the display medium layer 120 may also include an organic light-emitting material, an inorganic light-emitting material, other suitable materials, or a combination of said materials. In this case, the display panel 10 may be referred to as a light-emitting display panel. Further, based on a type of such self-luminescent material (e.g., the organic light-emitting material), the display panel 10 may also be referred to as an organic light-emitting display panel. In that case, the display device 1 may selectively omit the disposition of the backlight module 30. Other modifications are described in detail below with reference to FIG. 9. It should be noted that the reference numerals and a part of the contents in the previous embodiment are used in the following embodiments, in which identical or similar reference numerals indicate identical or similar elements, and repeated description of the same technical contents is omitted. The omitted part of the description can refer to the foregoing embodiment, which is not repeated in the following embodiments.

FIG. 9 is a schematic partial cross-sectional view of a display panel according to another embodiment of the disclosure. It should be noted that, the cross-sectional position of FIG. 9 corresponds to the position of the section line I-I′ of FIG. 2, and FIG. 9 only illustrates a partial structure of the sensing unit U1 in a display panel 70. However, according to content in the embodiments of FIG. 1 to FIG. 5, persons of ordinary skill in the art should be able to understand overall structure or layout of the display panel 70, as well as overall structure or layout of the display device including the display panel 70 and the circuit board 20.

Referring to FIG. 9 and FIG. 3 together, the display panel 70 of FIG. 9 is similar to the display panel 10 of FIG. 3 and can refer to the related description above. Thus, only the difference between the two is described below.

With reference to FIG. 9, the display panel 70 includes a pixel definition layer PDL disposed on the first electrode PE1. For instance, in this embodiment, the pixel definition layer PDL has an opening V for exposing the first electrode PE1. In other embodiments, it is also possible that the display panel 70 does not include the pixel definition layer PDL. In this embodiment, the pixel definition layer PDL is made of, for example, an organic material, but the disclosure is not limited thereto.

In this embodiment, a display medium layer 720 is located in the opening V and covers the exposed first electrode PE1. In this embodiment, the display medium layer 720 may include any light-emitting material well-known to persons of ordinary skill in the art. In this embodiment, it is exemplified that the light-emitting material included in the display medium layer 720 is an organic light-emitting material, and the organic light-emitting material may be, for example, a red organic light-emitting material, a green organic light-emitting material, a blue organic light-emitting material, a white organic light-emitting material, organic light-emitting materials of other colors, a combination of said light-emitting materials, but is not limited thereto. In this embodiment, because the display medium layer 720 includes the organic light-emitting material, the display panel 70 may be referred to as an organic light-emitting display panel.

In this embodiment, the second electrode CM1 disposed corresponding to the first electrode PE1 is disposed on the display medium layer 720. In this embodiment, a part of the common electrode layer CM corresponding to the first electrode PE1 is used as the second electrode CM1 of the pixel structure P1. In this embodiment, the first electrode PE1, the display medium layer 720 exemplified by the organic light-emitting material and the second electrode CM1 constitute an organic light-emitting diode, wherein the first electrode PE1 may be used as an anode of the organic light-emitting diode and the second electrode CM1 may be used as a cathode of the organic light-emitting diode. However, the disclosure is not limited to the above. In other embodiments, the first electrode PE1 may also be used as the cathode of the organic light-emitting diode, and the second electrode CM1 may also be used as the anode of the organic light-emitting diode. In this embodiment, it is exemplified that the first electrode PE1, the display medium layer 720 and the second electrode CM1 may be disposed in a manner of film layers on the first substrate 100, but is not limited thereto. In other embodiments, the light-emitting element may also be formed in advance by the first electrode PE1, the display medium layer 720 and the second electrode CM1 before being transferred onto the first substrate 100.

In this embodiment, the recess pattern C1 is configured to accommodate a film structure Q7 visibly protruded due to the first antenna A1, so as to prevent display quality from being affected by the spacers PS1 that failed to function normally for maintaining the proper gap between the first substrate 100 and the second substrate 110 when the film structure Q7 disposed on the first substrate 100 pushes against the planarization layer OC disposed on the second substrate 110. In this embodiment, although the film structure Q7 includes a part of the protection layer 150, the disclosure is not limited thereto. In fact, according to layout design, manufacturing process parameters for each layer and the like of the display panel 70, the film structure Q7 may also be a stacked-layer structure.

Based on content of FIG. 9 and content in the embodiments related to FIG. 1 to FIG. 5, with the sensing unit U1 including the first antenna A1 electrically connected to the data line DL1, the sensing unit U2 including the first antenna A2 electrically connected to the data line DL2′, the planarization layer OC having the recess pattern C1 that at least partially overlaps with the first antenna A1 along the normal direction Z and the recess pattern C2 that at least partially overlaps with the first antenna A2 along the normal direction Z, and the circuit board 20 having the second antennas B disposed corresponding to the first antennas A1 to A2, the display device including the display panel 70 and the circuit board 20 can transmit the pixel signal through wireless transmission and prevent the gap between the first substrate 100 and the second substrate 110 from being affected, so as to provide favorable display quality.

Furthermore, in the foregoing embodiments, the color filter pattern (e.g., the color filter patterns CF1 or the color filter patterns CF2) may also include quantum dots/quantum rods. In the foregoing embodiments, the color filter patterns (e.g., the color filter patterns CF1 or the color filter patterns CF2) may also be located on the first substrate 100 and located under the pixel electrodes. In this case, the color filter patterns (e.g., the color filter patterns CF1 or the color filter patterns CF2) may also regarded as being located between the first substrate 100 and the pixel electrodes. In the foregoing embodiments, it is also possible that at least one of the display panels 10, 40, 50, 60 and 70 further includes a quantum dot/quantum rod film, and the quantum dot/quantum rod film overlaps with the color filter patterns (e.g., the color filter patterns CF1 or the color filter patterns CF2). Moreover, the quantum dot/quantum rod film and the color filter patterns (e.g., the color filter patterns CF1 or the color filter patterns CF2) may be located on different substrates (e.g., respectively located on the first substrate 100 and the second substrate 110) or on the same substrate (e.g., the second substrate 110).

Although the present disclosure has been described with reference to the above embodiments, it will be apparent to one of ordinary skill in the art that modifications to the described embodiments may be made without departing from the spirit of the disclosure. Accordingly, the scope of the disclosure will be defined by the attached claims and not by the above detailed descriptions.

What is claimed is:

1. A display device, comprising:
a display panel, having a plurality of sensing units, each of the sensing units comprising:
a pixel array layer, disposed on a first substrate, the pixel array layer comprising a plurality of scan lines, a plurality of data lines and a plurality of pixel structures, wherein each of the pixel structures is electrically connected to one of the scan lines and one of the data lines;
a first antenna, disposed on the first substrate, and disposed corresponding to the scan lines and the data lines, wherein the first antenna is electrically connected to one of the data lines;
a planarization layer, disposed on a second substrate, wherein the second substrate is disposed opposite to the first substrate, the planarization layer has a recess pattern, and the recess pattern at least partially overlaps with the first antenna in a normal direction of the first substrate;
at least one spacer, disposed on the planarization layer, wherein the at least one spacer extends to the pixel array layer, and
a display medium layer, disposed between the first substrate and the second substrate; and
a circuit board, disposed under the display panel, wherein the circuit board has a plurality of second antennas disposed corresponding to the first antennas.

2. The display device of claim 1, wherein the first antennas in the sensing units are electrically connected to different data lines, respectively.

3. The display device of claim 1, wherein a minimum distance is provided between the first antenna and at least one of the corresponding scan lines or at least one of the corresponding data lines in the normal direction of the first substrate, wherein the minimum distance is between 0 μm and 5 μm.

4. The display device of claim 1, wherein the at least one spacer is in contact with the pixel array layer.

5. The display device of claim 1, wherein each of the first antennas has a thickness ranging from 1 μm to 5 μm, and each of the second antennas has a thickness ranging from 1 μm to 5 μm.

6. The display device of claim 1, wherein the first antennas and the second antennas are made of Al, Mo, Ti or Cu.

7. The display device of claim 1, wherein at least one of the first antennas is a single-turn coil or multiple-turn coils, and at least one of the second antennas is a single-turn coil or multiple-turn coils.

8. The display device of claim 1, wherein each of the pixel structures comprises:
an active element;
a first electrode, electrically connected to the active element; and
a second electrode, disposed corresponding to the first electrode, and structurally separated from the first electrode.

9. The display device of claim 1, wherein
each of the pixel structures comprises an active element and a first electrode, wherein the first electrode is electrically connected to the active element;
each of the sensing units further comprises a second electrode, disposed on the planarization layer.

10. The display device of claim 1, wherein each of the sensing units further comprises a light shielding pattern layer, disposed on the second substrate, wherein the light shielding pattern layer at least partially overlaps with the scan lines, the data lines and the first antenna in the normal direction of the first substrate.

11. The display device of claim 1, wherein each of the sensing units further comprises a plurality of color filter patterns, disposed on the second substrate, wherein the color filter patterns are disposed corresponding to the pixel structures.

12. The display device of claim 11, wherein the recess pattern does not overlap with the color filter patterns.

13. The display device of claim 1, further comprising: a backlight module, disposed under the display panel, wherein the backlight module is between the display panel and the circuit board.

14. The display device of claim 1, wherein the pixel array layer is not in contact with the planarization layer.
